(19) United States
(12) Patent Application Publication
(10) Pub. No.: US 2010/0164079 A1
(43) Pub. Date: Jul. 1, 2010

(54) METHOD OF MANUFACTURING AN ASSEMBLY AND ASSEMBLY

(75) Inventors: Ronald Dekker, Eindhoven (NL); Marc Andre De Samber, Eindhoven (NL); Wilhelmus Hendrikus De Haas, Eindhoven (NL); Theodorus Martinus Michielsen, Eindhoven (NL); Franciscus Adrianus Cornelis Maria Schoofs, Eindhoven (NL); Nicolaas Johannes Anthonius Van Veen, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., Eindhoven (NL)

(21) Appl. No.: 11/993,266

(22) PCT Filed: Jun. 23, 2006
(86) PCT No.: PCT/IB06/52040

§ 371 Date: Dec. 20, 2007

(30) Foreign Application Priority Data
Jun. 29, 2005 (EP) 05105838.6

(51) Int. Cl. H01L 23/488; H01L 21/56; H01L 23/28

(52) U.S. Cl. 257/676; 438/124; 257/692; 438/123; 257/E21.502; 257/E23.031; 257/E23.023; 257/E23.116

(57) ABSTRACT

The assembly (100) comprises a laterally limited semiconductor substrate region (15) in which an electrical element (20) is defined. Thereon, an interconnect structure (21) is present. This is provided, at its first side (101) with contact pads (25,26) for coupling to an electric device (30), and at its second side (102) with connections (20) to the electrical element (11). Terminals (52,53) are present at the second side (102) of the interconnect structure (21), and coupled to the interconnect structure (21) through extensions (22,23) that are laterally displaced and isolated from the semiconductor substrate region (15). An electric device (30) is assembled to the first side (101) of the interconnect structure (21), and an encapsulation (40) extending on the first side (101) of the interconnect structure (21) so as to support it and encapsulating the electric device (30) is present.

The invention relates to a method of manufacturing a semiconductor assembly comprising the steps of:

providing a carrier comprising a semiconductor substrate with a first side and an opposite second side, and with at least one electrical element defined in the substrate at the first side, further comprising a plurality of contact pads;

attaching and electrically coupling at least one active device to the contact pads; and

patterning the semiconductor substrate from its second side to form terminals that are electrically isolated from the electrical element.

The invention also relates to an assembly obtainable therewith.

The invention further relates to a carrier for use in the said method.

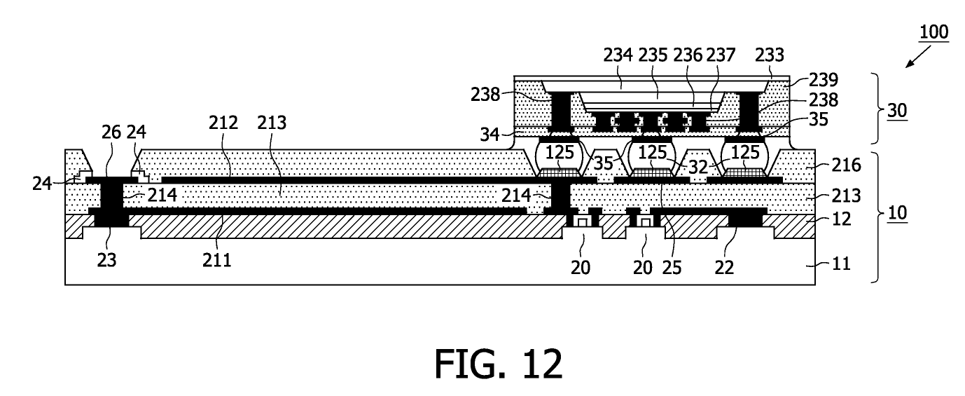

Such a method is known from U.S. Pat. No. 6,075,279, and particularly FIG. 12 therein. The carrier comprises herein a semiconductor substrate with a plurality of transistors. It further comprises conductive paths through the substrate, particularly n⁺-doped substrate regions. Contact pads are coupled to the electrodes of the transistors. A second semiconductor substrate is assembled to the first substrate. This second substrate is a wiring substrate and comprises a plurality of transistors and interconnects, that suitably form an integrated circuit. This integrated circuit preferably functions as a control IC for the transistors defined in the carrier. Contact pads on the first and the second substrate and mutually connected with solder balls. The space between the first and the second substrate around the solder balls is filled with a insulating adhesive resin of silicon, epoxy or polyimide. This resin ensures mutual adhesion of the first and second substrate. This is achieved in particular in that the resin layer is thermoset in a heating treatment. This thermosetting also causes the resin to shrink and to harden. As the first and second substrate both comprise silicon, there is no difference in thermal expansion coefficients and cracking of the solder balls as a result of the stress as a result of different thermal expansion is prevented.

Thereafter, the semiconductor substrate is patterned from its second side by making slit holes, particularly by dicing. The slit holes extend into the resin layer, in order to isolate electrically the conductive paths from the transistors. The slit holes separate the conductive paths from the transistors, thus allowing that the back side of the conductive paths are used as terminals for the device. These terminals are again secured to contact pads on a packaging substrate. This is however done only after the slit holes are filled and the substrates are singulated into individual products.

It is a disadvantage of the known method, that the risk of yield loss is substantial. The cause for this yield loss is in particular, that assembly of the first and the second substrate has to be carried out on wafer-level. Thus any device on the substrates is assembled, also if it does not function properly. If thus 3% of the devices on each of the substrates does not function properly, the resulting yield loss will be near to 6%.

It is therefore a first object of the present invention to provide a manufacturing method of the kind described in the opening paragraph with a reduced yield loss.

The first object is achieved in that:

the carrier comprises an interconnect structure that is present on the first side of the substrate, in which are defined the plurality of contact pads and extensions to the first side of the substrate, to which extensions the terminals are coupled, as well as interconnects from and to the at least one electrical element,

the active device that is coupled to the carrier has a smaller surface area than the carrier and is encapsulated, and

the semiconductor substrate of the carrier is thinned and selectively removed so as to create islands of semiconductor material.

The second object is achieved in that.

The invention solves the problem of yield loss, in that the individual devices are assembled to the carrier that laterally extends beyond the individual devices. And then the individual devices are encapsulated. However, such a chip on chip assembly creates other problems. First of all, there tends to be a difference in the coefficients of thermal expansion between the encapsulation and the carrier substrate. The stress resulting from these differences during thermal cycling must be released anywhere. The use of a hardened thermoset resin between the carrier substrate and the active device might thus not be most adequate. However, it appears very difficult to dice the carrier substrate with a sawing technique without such a hardened resin.

These related problems are now solved in the invention. The approach thereof is that the carrier substrate is a carrier only during the assembly. As soon as there is applied an encapsulation, this can take over the role of carrier. The semiconductor substrate is then removed as far as it is not functional. This removal extends so far that merely islands of semiconductor material will be left; and this creation of islands leads to an assembly that may appropriately withstand the stresses of thermal cycling.

During thermal cycling, the assembly is attached to a printed circuit board. Heat generated in the active device or in the carrier substrate will dissipate. A certain heat flow will be created with the corresponding expansion, and subsequently contraction. Moreover, the overall temperature may be different from the assembly temperature, leading to an inherent stress.

In the assembly of the invention as attached on the printed circuit board, four components may be distinguished: the active device, the encapsulation, the island created from the carrier substrate and the printed circuit board. For reasons of clarity, the interconnect structure is herein assumed to be part of the encapsulation. By patterning the carrier substrate into islands, solely the printed circuit board and the encapsulation extend laterally over the complete surface area. This is suitable, since the encapsulation has a coefficient of thermal expansion—also referred to as CTE—that matches that of the printed circuit board best. Preferably, the CTE of the encapsulation is smaller than that of the printed circuit board, most preferably between 10 and 15 ppm/K in the lateral direction, whereas the CTE of the printed circuit board is 17 ppm/K in the lateral direction. If needed, a component for stress release, such as a layer of a compliant material, may be present between both. The thermal behaviour of the active device with respect to the encapsulation is not different, at least in first order, with respect to the situation on a simple carrier.

If the islands of semiconductor material are not connected to the printed circuit board, then the only relevant interface is that between the islands and the encapsulation. Here, the difference will be smaller than that with the printed circuit board. Moreover, the islands have a dimension of a few millimeters or less. The stress build-up is thus limited. Moreover, due to the larger CTE of the encapsulation, the islands are put on compressive stress during the manufacture. This compressive stress is an inherent barrier against the formation of cracks.

If the islands are also connected to the printed circuit board, then there are two relevant interfaces. The stress is then dependent on the difference in thermal expansion between the encapsulation and the printed circuit board. However, the means for connection between the printed circuit board and these islands, such as solder balls and underfill, inherently also are stress-releasing. Additionally, the limited thickness of the island of semiconductor material makes it relatively flexible, so that the islands may deform themselves to a certain extent in order to relieve stress.

In order to optimize the island-structure of the carrier substrate, the oxide layer generally present on top of the carrier substrate may be removed so as to create a groove around the island. Hence, therewith not just the carrier substrate but also the oxide layer on top thereof is not continuous. Instead of a groove-like structure, any other patterning structure may be applied, such that the oxide layer is divided into a plurality of islands. Suitably, an additional passivation layer is applied after patterning of the oxide. Even if this is an oxide or a nitride, its shape will be such that the oxide islands may be movable with respect to another to at least a certain extent.

In a further embodiment, the interconnect structure comprises a compliant dielectric material. A compliant material is known to relieve stress due to its high extent of deformability. Particular, organic dielectric layers are preferred over inorganic layers to be used as a layer that extends over the complete surface area of the assembly.

The islands into which the carrier substrate is structured, are preferably mesa-shaped. That is: a cross-section perpendicular to the substrate surface is then substantially trapezium-shaped. A mesa-structure is obtained in that the substrate is first thinned and then wet-chemically etched according to a desired pattern. In the plane parallel to the substrate surface, the islands may have any shape. It is however preferred that their circumference is free of corners, and most preferably circular.

The thinning of the carrier substrate may be carried out before and after the assembly of the active devices to the carrier. While it is suitable to assemble active devices on a thick and rigid carrier, solder connections are sensitive to any mechanical forces and thus also to vibrations occurring as a consequence of grinding. The carrier substrate may therefore be thinned, at least to a certain extent before the assembly step. In one suitable embodiment, the carrier substrate is also provided with a mask on its second side before the assembly step, and after the thinning step. A suitable mask is for instance Ni, Au, Pd, TiW or a combination of such materials, but also a foil-alike photoresist could be used.

Particularly if the thinning is carried after the assembly, an underfilling material may be applied onto the carrier substrate that melts on gentle heating. Such a gentle heating leads to sinking of the active device through the underfilling material, and hence to a mechanical connection of carrier and active devices. The step of providing the electrical connection,—e.g. making the solder chemically react with metal on the opposite surface to form a soldered connection—may then be carried out after the thinning step.

The encapsulation may be chosen to be a metal substrate, a glass substrate attached with an adhesive or an overmoulded encapsulation. It will be clear that the choice of the encapsulation affects the thermal behaviour of the assembly.

The overmoulded encapsulation has coefficient of thermal expansion between that of the silicon substrate and the printed circuit board. Its specific coefficient can be tuned through the amount of filler. Most suitably, this coefficient is chosen to be in the range between 10 and 15 ppm/K. This allows matching to the printed circuit board, while the difference with the semiconductor materials inside the assembly does not get too big.

Overmoulding of a large surface area, such as a wafer, has however the tendency to create warpage during assembly. Processing of the resulting bent carrier substrate is then difficult. However, one may apply an etching mask at the second side of the carrier substrate before the overmoulding, if also the substrate is thinned before the overmoulding step. Etching, and particularly wet-etching, may then be carried out even if the assembly is not planar. As a result of the etching step, the warpage effect will be substantially reduced. Alternatively, one may apply the overmoulding in two or more areas on the carrier substrate, generally called maps. A surface modification on the first side of the carrier substrate may help to prevent deposition of the overmoulded material outside the desired maps.

Most suitably, the electric device or the complete carrier substrate is provided with a coating of an elastic material (lower Young's modulus than the overmoulded material). Such a coating is known as wafer coating or chip coating. Herein, however, it is also applied over the backside of the electric device. The aim of this coating is to release stresses particularly in the lateral dimension between electric device and moulding compound.

The metal substrate effectively has a coefficient of thermal expansion that is, at least in a direction parallel to the substrate surface, comparable to that of the printed circuit. It has the advantage of achieving heat spreading. This improved heat spreading effectively leads to a lower frequency and smaller amplitude of the thermal cycling. Thermal and electrical isolation between metal substrate, the active device and the carrier may be chosen in relation to the specific application. One specific option is here the creation of a stripline, of which the signal line is sandwiched between a first and a second ground plane. Such a stripline is very suitable for devices operating at ultrahigh frequencies.

The glass substrate with adhesive is in fact a tow-layered or even multilayered encapsulation. The adhesive may act also as a stress-releasing layer. The glass substrate is suitably chosen to have a coefficient of thermal expansion that is relatively near to that of a printed circuit board in its lateral direction. This is achieved with a suitable choice of the glass composition.

In an even further embodiment, the encapsulation is provided with one or more through-holes. In the case of an electrically insulating encapsulation, the through-holes are subsequently metallized. This operation is known per se, particularly for glass substrate. In this manner, contacts may be provided also at the first side of the assembly. This allows a further stacking of devices.

The assembly step during the manufacture usually involves the provision of a soldered connection. However, also for the provision of the terminals to an external board, use is suitably made of solder balls. It is therefore preferable, that the solder balls used for the connection of the electric device and the carrier substrate have a higher melting point that those used for the connection of the carrier substrate to the printed circuit board. Examples to be combined with the Sn—Ag—Cu solder for the connection for the printed circuit board, are for instance Pb—Sn and Au—Sn. Therewith, remelting of the first mentioned solder is prevented. Such remelting could give rise to stability problems, e.g. deformation of the solder balls and the carrier substrate. This is particularly a risk in a construction wherein the solder balls are stacked. Then, there is merely a metal bond pad that separates both solder balls.

The provision of a soldered connection inside may also be effected in that the solder balls are sunk through an insulating layer that liquefies on heating. As such, no separate underfilling material need to be applied. Additionally, the formation of a soldered connection may be postponed to a later step in the manufacture.

In order to minimize the height of the assembly, the soldered connection between the electric device and the carrier substrate may be implemented with solder caps. Such caps may for instance be applied as immersion solder bumping.

Most suitably, the solder material used for the connection between the electric device and the carrier substrate is a two-phase solder material with as a second phase particles that are thermodynamically metastable. This solder material, that has been described in the non-prepublished application PCT/IB2005/051547 (PHNL040567), allows the provision of solder on oxidized surfaces without the need to remove the oxide first. It is particularly suitable for aluminium. Hence, in this assembly, it allows to use aluminium or an aluminium alloy such as Al—Si, Al—Cu for the conductor tracks in the interconnect structure. This has the advantage that Al and the usual alloys thereof is relatively ductile.

It is a second object of the invention to provide an assembly that may be made according to the invention with limited yield loss and may withstand stresses of thermal cycling.

This object is achieved in that the assembly comprises:

a laterally limited semiconductor substrate region in which an electrical element is defined;

an interconnect structure overlying the substrate region and having an first side and a second side, which structure is at its first side provided with contact pads for coupling to an electric device, and is at its second side provided with connections to the electrical element,

terminals that are present at the second side of the interconnect structure, and coupled to the interconnect structure through extensions that are laterally displaced and isolated from the semiconductor substrate region,

an electric device coupled to the first side of the interconnect structure, and an encapsulation extending on the first side of the interconnect structure and encapsulating the electric device.

As explained with reference to the method, the resulting device withstands thermal cycling due to the fact that the semiconductor regions are islands on the encapsulation and the interconnect structure. The encapsulation acts herein as the support.

The devices defined in the carrier substrate, at least partially, are for instance trench capacitors, trench batteries, transistors, diodes, varactors. For an RF application, trench capacitors are suitable in view of their high capacitance density, and varactors in view of their tenability. Pin-diodes are suitable as switches. Use of pindiodes in mesa-structures additionally has the advantage that any mutual influence between the pindiodes through the substrate is prevented. The pindiodes are preferably lateral pindiodes. These can be easily connected from the top side. Also, lateral pindiodes have the advantage that pindiodes with different dimensions may be integrated on one substrate. The different dimensions result in different properties like breakdown, isolation and on-resistance, and the like. Within one front-end of a mobile phone, including a power amplifier, band switches and impedance matching, and optionally a transceiver, pindiodes with different dimensions are highly preferred.

For protection of active devices against electrostatic discharge (ESD) pulses, diodes such as Zener diodes or back-to-back diodes could well be integrated into the carrier substrate. Here, the carrier substrate is suitable doped to be electrically conducting. Also the island is suitable connected with a printed circuit board for the removal of the charge and heat generated during the discharge. ESD protection devices are particularly needed in combination with integrated circuits as active devices, and especially for mobile applications such as a mobile phone. Moreover, the shrinkage of dimensions of integrated circuits make these more vulnerable, and hence increase the importance of electrostatic discharge devices and circuits. Capacitors and resistors may be present in the interconnect structure for filtering of the signal.

For identification of active devices, the island of semiconductor material may contain identification circuits, as well as circuits for wireless transmission of signals. Antennas may be present in the interconnect structure.

For power applications, power transistors may be present in the carrier substrate. Also in this application, the islands are suitable connected electrically with the printed circuit board. The active device is herein for instance a control IC for the control of the individual power transistors.

For optoelectronical applications, light emitting diodes and/or photodiodes may be present in the carrier substrate. Optionally, the carrier substrate thereto contains a III-V semiconductor substrate material instead of silicon. The active device is in this embodiment suitable a driver IC.

These and other aspects of the method and the assembly will be further explained with reference to the Figures, that are diagrammatical and not drawn to scale, and in which the same numbers in different figures refer to the same or equivalent parts, in which:

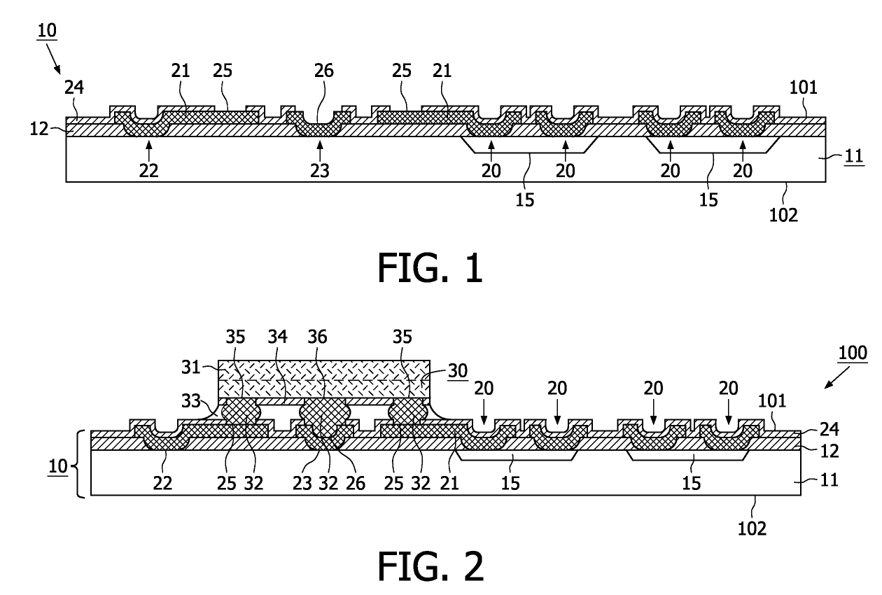

FIGS. 1-6 show in cross-sectional view several stages in a first embodiment of the assembly method;

FIGS. 7-9 show in cross-sectional view several stages in a second embodiment of the assembly method, and

FIGS. 10-14 show in cross-sectional view several stages in a third embodiment of the assembly method.

FIGS. 1-6 show in diagrammatical, cross-sectional view a first embodiment of the method of the invention for obtaining a system in a package. Although the order of the steps is preferred, another order is not excluded. Although merely one individual component is shown, it will be understood that the process is suitably carried out at wafer level. These and following Figures are not drawn on scale.

FIG. 1 shows the carrier 10. In this example, the carrier 10 comprises a silicon substrate 11 with a first side 101 and an opposite second side 102. It is provided with a plurality of electrical elements 20, that are provided in areas 15 of the substrate 11, that will be designed into mesas. The electrical elements 20 are for instance capacitors and/or switches and sensors. Examples for use in RF applications include trench capacitors, pin diodes and isolated circuit blocks, such as a VCO. The components are in this embodiment preferably components with a low power consumption, as there is no direct connection to ground. Their presence in mesas 15 furthermore provided an excellent isolation, which can be fully exploited in components that are sensitive for parasitic interaction through the substrate 11. Although not indicated here, the elements 20 may also be present partly or completely on the substrate surface 12. Examples hereof are LC circuits, capacitors with a ferroelectric dielectricum and tunable capacitors and switches, such as in particular MEMS-elements. In addition, combinations are useful, such as trench capacitors that have a high capacitance, and MEMS elements that are tunable. Examples outside RF applications include for instance sensors, but also an individual or a number of transistors. For the RF application, the use of a high-ohmic substrate is highly advantage. Such a substrate 11 may be prepared by implantation of particles or irradiation with e-beam. Furthermore, the substrate 11 may be made amorphous near to its first side 101.

At the first side 101 of the substrate 11 an oxide layer 12 is present. This is suitably a thermal oxide. Apertures are made in the oxide layer 12 to provide an interconnect 21 to the electric elements 20, and also to provide extensions 22, 23 for provision of external connections. They are to be exposed after partial removal of the substrate 11 to form the terminals 52, 53. Although the interconnect 21 is herein shown to be a single layer, a plurality of layers may be used alternatively. This is particularly suitable, when electrical elements such as resistors, thin-film capacitors and inductors are defined within this interconnect (structure) 21. The interconnect (structure) 21 is covered with a passivation layer 24 of for instance silicon nitride. The passivation layer 24 is opened at selected locations to create top side bond pads 25,26. Although all bond pads 22, 23, 25,26 and interconnects to the electric elements 20 are shown in this figure to be of the same size, this need not to be an accurate representation of the real design.

Suitable, at least one of the top side bond pads 25,26 is designed as a test pad, i.e. connected to an underlying test structure. This allows to test the carrier substrate 10 before any further components are assembled to it. It is not needed that each unit is provided with a test structure. Test to be carried out are primarily conventional electrical tests.

For RF applications, inductors are needed with a high quality factor. This may be achieved with the use of a relatively thick metal layer, for instance in the order of 0.5 microns or more, particularly 1.0 microns or more, if aluminium or an aluminium alloy is used as the metal. This same layer is simultaneously highly suitable for support of the bond pads.

Although not shown in this Figure, the top side bond pads 25,26 may be provided with an additional support and adhesion cover, such as known in the packaging field as underbump metallization. This metallization comprises for instance a stack of layers of NiPdAu. The stack of layers depends however on the underlying metal. If the interconnect 21 is made of copper, barrier layers may be needed to prevent diffusion of the copper. However, in a suitable modification that is highly suitable in combination with an interconnect 21 of aluminium or aluminium alloy, such additional underbump metallization is not needed. Instead, the solder bump material to be provided on the interconnect 21 may be chosen to include metastable particles. On heating such particles may reduce the oxidized aluminium and form a stable alloy therewith. This principle is described in the non-prepublished patent application PCT/IB2005/051547 (PHNL040567) that is included herein by reference. The use of this solder is most suitable in combination with a thick metal layer in which also inductors are integrated. It is suitable that some areas are not covered by any metallization, and are defined as separation lanes.

FIG. 2 shows the assembly 100 that results after providing an active device 30 onto the carrier 10. The active device 30 is assembled in a flip-chip orientation to the carrier 10, such that its bond pads 35, 36 face the top side bond pads 25,26 in the carrier 10, and the bond pads can be mutually connected with solder bumps 32. A passivation layer 34 is present for protecting purposes, such as generally known in the art. Instead of solder bumps 32 use could be made of solder caps with a reduced height. Such solder caps may be applied, for instance, in a process known per se as immersion soldering bumping. The limitation of the height of the active device 30 on the carrier 10 appears advantageous for the reliability of the process to follow. In that respect, it is furthermore preferred that the active device 30 has a thinned substrate 31.

The active device 30 may include one or more of the following functions: it may be an acoustic device, such as a bulk acoustic wave filter. It may be an impedance matching device, including an LC-filter as well as switches, particularly MEMS components. It may be a transceiver or at least part thereof. It may be or include a power transistor, and be used as a power amplifier or as a power management unit. Evidently, the active device 30 could also be applied in a face-up orientation and be connected to top side bond pads 25,26 with wirebonds. However, the present construction with a flip-chip orientation is highly suitable, in that a very direct connection may be made from the active device 30 to an external board, as will become apparent from later stages in the process. This direct connection is needed for the grounding, as in transceivers or power amplifiers and the like, or for the provision of power from a battery, such as in a power management unit, or for the dissipation of heat. Although merely one active device 30 is shown, several of them may be present in one unit of the assembly. This allows to create any functional system as desired, such as a complete front-end of a mobile phone with power amplifier, transceiver and matching functions.

An underfill 33 is provided between the active device 30 and the carrier 10. Although not shown here, use can be made of an underfill 33 that is provided on the carrier 10 in advance of the assembly of the active device 30 thereto. The underfill will then be present on the complete carrier, if its flow is not limited. Suitably, it is provided as a foil, which is however not essential. Typically, it is made of an acrylate or a polyimide type of material. This type of underfill may be softened, for instance by heating to about 100° C. The softening makes it mechanically weak, and the solder bumps will sink through this underfilling layer as a consequence of their weight.

A further advantage of the use of such a material is, that the solder bumps 32 need not to be electrically connected at this stage of the process, at which the solder bumps 32 are placed at the carrier 10; or stated more precisely: the solder bumps need not to react to the bond pads 22,23 of the carrier 10 to form intermetallic compounds. This is an advantage for the reliability of the construction in all the stages of the manufacturing. Solder balls 32 are inherently mechanically weak areas in an assembly 100. They need to release stress during all steps of the assembly as well as during use, which stress originates from difference in thermal expansion between different components in the assembly. If this is not possible, then cracks may form in the solder balls, or delamination of the solder balls from either bond pads takes place. This leads to a malfunctioning of the assembly. While additional solder balls could be used to act as a secondary path, this is generally not desired. However, in the present process, the solder balls 32 also need to withstand the mechanical forces that appear as a result of the further processing steps. These steps may include grinding and etching of the carrier substrate. While grinding involves strong vibrational forces, etching may lead to bending of the carrier 10, e.g. warpage. If the solder bumps 32 have already been chemically and electrically connected to the carrier 10, they need to withstand these mechanical forces. If only placed on the carrier, this is not necessary.

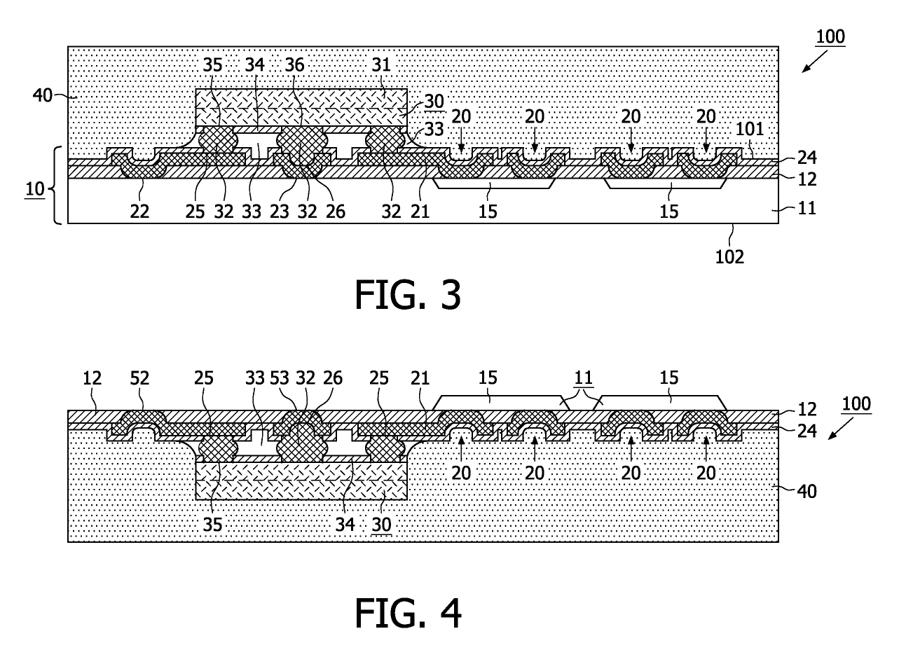

FIG. 3 shows the assembly 100 after a further process step, in which an encapsulation 40 is provided. In addition to offering chemical and mechanical protection to the active devices 30 and any wirebonds present, the encapsulation 40 should have a substantially planar top surface 41. The planarity should be sufficient for laying the assembly with it on an apparatus and performing operations on the substrate 11 of the carrier 10. In this embodiment, the encapsulation 40 is an epoxy overmould. Alternatively, use may be made of a metal overmould or of an adhesive and a glass layer. An even further alternative is the use of a protecting overmould with a suitable carrier, such as a leadframe alike construction. In a further modification, the encapsulation 40 comprises a plurality of layers, of which the first one has a planarizing effect. Most suitable, the thermal expansion coefficient of this planarizing layer thereof matches or is similar to that of the active device 30. Furthermore, a layer with a low Young's modulus to release stresses may be applied before the overmould.

FIG. 4 shows the device after a couple of further process steps, in which the substrate 11 is partially removed. In a first step, the substrate 11 is thinned to a thickness in the order of 30-100 microns, and preferably about 50-60 microns. Grinding is the most widely known option therefore. However, in a modification of the process, the grinding has been carried out before the assembly of the active device 30 to the carrier 10. Suitably, a support layer is then attached to the carrier substrate 11 so as to stabilize the carrier 10. This support layer is removed again at this stage of the process, for instance by dissolving an adhesive between the support layer and the carrier substrate 11, by dissolving the complete support layer, by peeling off the support layer. Other methods as well as combinations may be applied alternatively. The removal of the support, for instance by grinding, is followed by a further wet-chemical etching step. Thereafter, the carrier substrate 11 is selectively etched, so that the mesas 15 with the electric elements 20 are maintained, while the substrate 11 is elsewhere removed to expose extensions 22,23 of the interconnect structure 21, and therewith form the terminals 52,53. Alternatively, an encapsulating layer may be provided on the second side, and patterned to expose the extensions 22, 23. The terminals are then formed on this encapsulating layer. A suitable material is for instance a polyimide or the like. This has the effect that the carrier substrate may be put under compressive stress both from the first side and from the second side.

At this stage, after removal of the substrate and before provision of solder to the terminals, final testing may be carried out. Aim of such final testing is particularly to check whether all soldered connections between the contact pads on the carrier substrate and the active device 30 allow electrical coupling. Additionally, one may carry out some test to check whether the assembly survives bending.

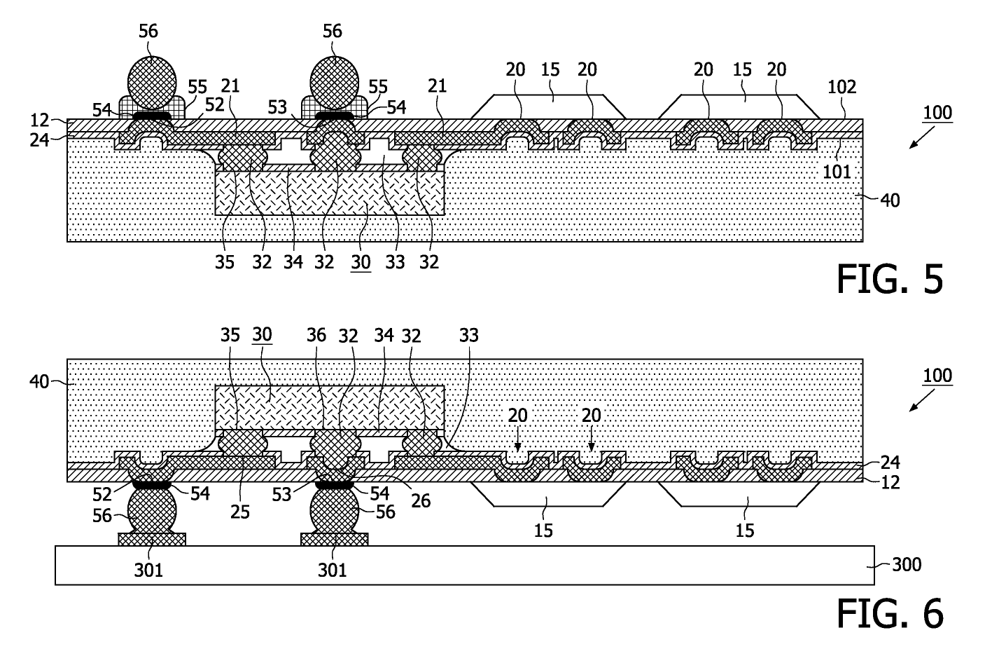

FIG. 5 shows the assembly after the final assembly steps. Herein, the terminals 52, 53 are herein provided with a metallization 54 so as to strengthen the structure and improve the bondability. Thereafter, a flux 55 is provided by screenprinting. Finally, solder balls 56 are attached thereto. The flux 55 herein assures that the balls do not spread over the complete second side of the carrier substrate 10. Suitably, the solder balls 56 have a larger pitch than the solder balls 32, in order that active devices 30 with many contact pads 25 on a small surface area can be combined with printed circuit boards that generally have a lower resolution.

FIG. 6 shows the assembly 100 in its position on a board 300. The solder balls 56 herein couple the terminals 52, 53 to the corresponding contact pads 301 of the board. The board 300 is generally a printed circuit board, such as made of an FR4-material, but may alternatively be a flexible carrier such as a tape. Furthermore, the board 300 may also be part of the system-in-a-package. It may then comprise functionality such as passive components and interconnects, and be of organic or ceramic material. This seems an appropriate system particularly for RF applications. It has the advantage from the design point of view, that the terminals 52, 53 need not to be positioned in an array.

If the board is not part of the system, then most preferably the terminals 52, 53 are positioned in an array. The assembly 100 is then preferably designed such, that the terminals 52, 53 that provide a direct connection to the active device 30 are provided near to a first edge of the assembly. The terminals 52, 53 that provide a connection to the electrical elements in the mesa-shaped islands 15 are preferably present near to an opposite edge of the assembly. In this manner, the assembly 100 is effectively partitioned in a number of areas.

FIGS. 7-9 show in diagrammatical, cross-sectional view a second embodiment of the assembly method of the invention, and the resulting assembly. The assembly of this embodiment comprises power devices, and particularly those of the vertical MOS type. Such power devices are designed so as to reduce as much as possible the on resistance. This implies that the devices are made in a heavily doped, n-type silicon substrate that acts as a drain or a collector contact. The disadvantage of this approach is however, that merely one transistor may be present per die; otherwise the drains or collectors of the present transistors would be connected.

One solution to reduce such a problem is the structuring of the substrate into mesas. This is known per se from U.S. Pat. No. 5,753,537. Although this technique may be used to create a higher integration density, it does not result in a system-in-a package with a plurality of elements forming a functional entity. Another approach is disclosed in U.S. Pat. No. 6,075,279. This approach proposes the assembly of a first and a second wafer to each other to create vertical integration. Subsequently, the first wafer is patterned mechanically. It is herein important that the resulting slits extend through the first wafer to the area between the wafers that is filled with resin. Otherwise, an insufficient isolation of the neighbouring electrodes in the first wafer results. These slits are subsequently filled with insulating resin.

This approach however has the disadvantage that wafers must be assembled, which rapidly leads to yield loss, as for non-functioning it is sufficient that one of the transistors does not function adequately. Moreover, dry etching of holes through a wafer is a time-consuming process which is thus also expensive.

In the present invention, individual devices are integrated on the first wafer, that is provided with the interconnect structure. The first wafer is subsequently thinned and patterned with wet-etching techniques, therewith reducing the first wafer to a couple of islands that derive their mechanical behaviour from the assembly structure to which they are attached, and not from themselves. The islands herein do not correspond to one transistor, as in the device of U.S. Pat. No. 6,075,279, but to a contact pad.

In order to provide the required mechanical stability during all phases of the assembly and during use, the individual devices are encapsulated. Furthermore, there is a flexible and preferably compliant layer on top of the first wafer in this embodiment. Vias extend through this flexible layer and contact pads to which the individual devices are coupled, are present only on this flexible layer. In this manner, a mechanical decoupling is arranged.

FIG. 7 shows a cross-sectional view of the carrier 10. It comprises a silicon substrate 11 with a first layer 111 that is highly doped of the n-type. The dopant concentration is in the order of 10¹⁹/cm³. Above the n++-layer 111 of the substrate 11 a substantially undoped substrate layer 112 is present. This intrinsic layer 112 acts as the channel of the transistor. A deep diffusion 113 extends from the n++-layer 111 through the undoped layer 112 to one or more extensions 22 in the interconnect structure 21. Additionally, electrical elements 20 are defined in the substrate, which are in this example vertical MOS devices. The substrate 111 acts herein as the drain, while the source and the gate are present at the top side. These vertical MOS devices are conventional. Alternatively, trench MOS devices, or bipolar devices could be applied. The extension or contact pad 22 is electrically coupled to the first of the elements 20 (or actually the same one) by an interconnect 21. The second element 20 is provided with such an interconnect as well, however to another, not shown extension 22.

The elements 20 and the interconnect structure with its extensions 22 are covered with a dielectric layer 120. This is preferably a compliant layer, such as polyimide. A suitable compliant layer is an organic material that has a small Young's modulus and a low glass transition temperature. This type of materials is in use in the packaging industry for wafercoating, rerouting layers in a chip scale package and die attach materials for integrated circuits in ball grid array packages. If the grinding is carried out after that active devices 30 have been assembled to the carrier, it is preferred to use a material with a glass transition temperature above room temperature. This ensures that during grinding at room temperature the assembly of carrier substrate and encapsulation is sufficiently mechanically rigid. Additionally, a relative rigidity at room temperature appears to be suitable for the assembly step itself. The thickness of the dielectric layer 120 is preferably in the range of 0.5-20 microns, most preferably in the order of 1-5 microns. This is a thickness that allows sufficient flexibility, while vertical interconnect areas 121 can be manufactured properly. Effectively, the dielectric layer 120 also forms the electrical isolation between neighbouring elements 20. Vertical interconnect areas 121 extend through the dielectric layer 120. Interconnects 122 are present on the dielectric layer 120 and extend to contact pads 25. These contact pads 25 are provided with a material 125 suitable for bonding, such as NiAu. This material 125, also called under bump metallization can be applied by electroless growth. Although shown here as merely an underbump metallization, it is not excluded that also solder bumps are applied. The structure is finally covered with a passivation layer 24, for which for instance Si₃N₄ is chosen.

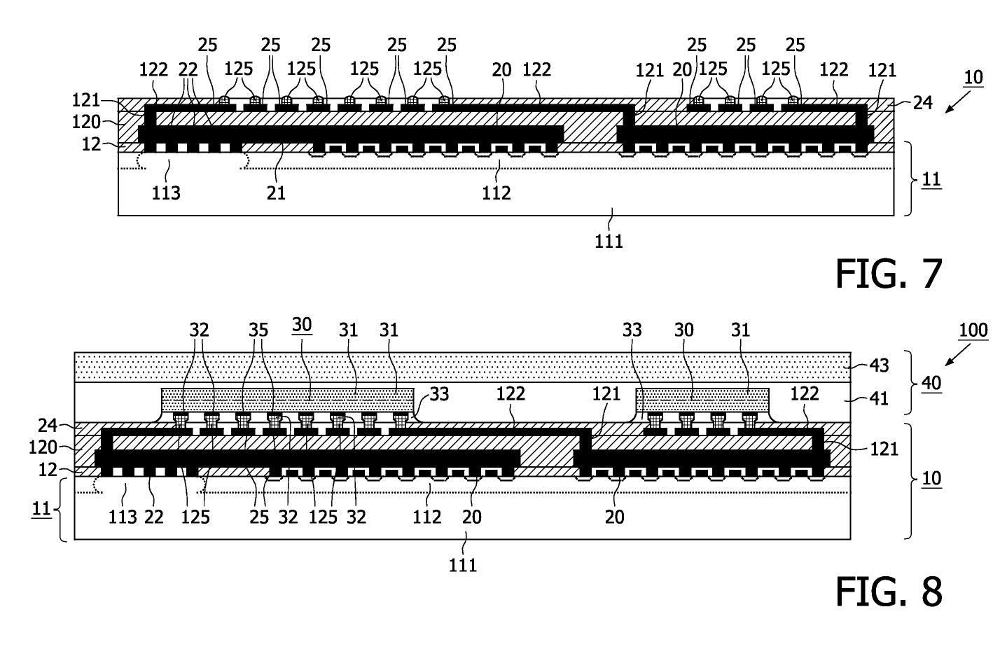

FIG. 8 shows the assembly 100 after assembling the devices 30 and providing an encapsulation 40. The devices 30 are assembled to the carrier 10 with the flip-chip technique using solder balls 32, that had been provided on the devices 30 before the assembly. Preferably, an underfill material 33 is used. This underfill 33 may be applied after or before the assembly, as discussed before with respect to the first embodiment. Solder caps could be used instead of solder balls 32. Alternative connection techniques, such as anisotropically conductive glue, may be applied. The devices 30 preferably have a thinned substrate 31. In a heating step, the solder balls 32 on the active device 30 and the underbump metallization 125 are joined to a soldered connection 32.

The devices 30 are here in particular designed for controlling of the electrical elements 20, and preferably integrated circuits. Such control ICs are known per se to the skilled person in the field. One advantage of the integration into a single package is evidently that the board onto which the assembly 100 is to be positioned may be simplified. No interconnects between the control IC and the controlled elements need to be provided, and the number of terminals of the assembly 100 may be reduced. Another advantage of this structure is that the distance between the control IC and the electrical elements is rather short and simple. This may be exploited in the use of simple communication protocols. Additionally, the integration allows to provide additional feedback mechanisms from the elements 20 to the control IC 30, in order to improve the control

The encapsulation 40 comprises in this example an adhesive 41 and a glass substrate 43 covering the complete assembly. An epoxy overmould such as used in the first example may be used alternatively. The application of adhesive 41 and glass substrate 43 appears very suitable for assemblies, in which large differences in temperatures are expected, such as power transistors. The adhesive 41 is primarily present between the active devices 30 and can be chosen to be highly deformable. Therewith local and relatively short amounts of stresses can be released properly.

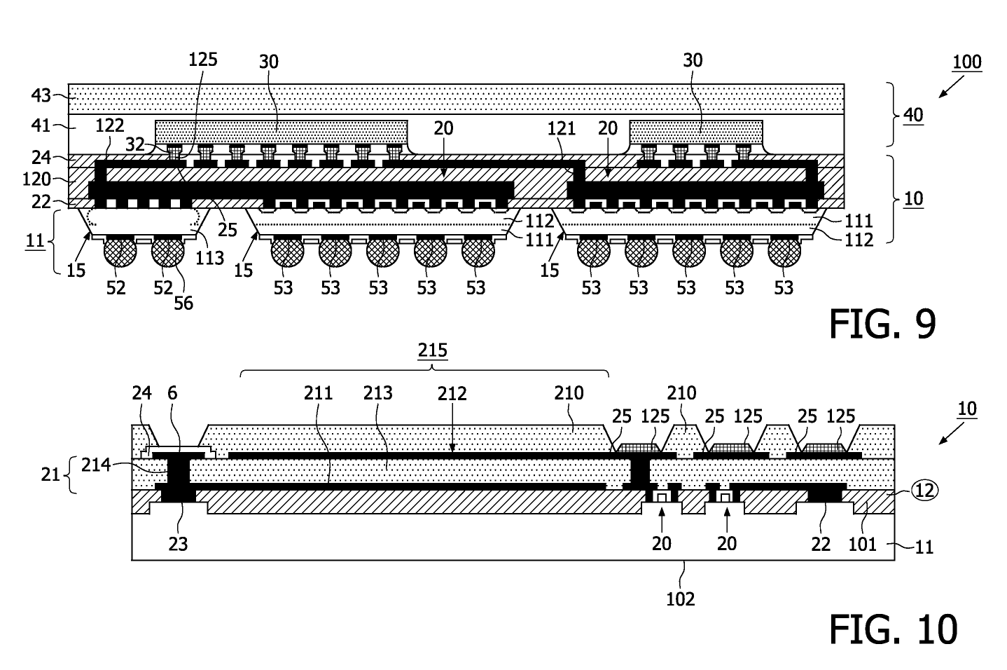

FIG. 9 shows the assembly 100 after thinning and patterning the substrate 11 of the carrier. This differs from the first embodiment in that the mesas 15 are used as well as interconnect to the terminals 52,53 for coupling to an external component. Per mesa 15 more than one terminal 52, 53 is defined, which may but need not to be used for one and the same signal or ground connection. The plurality of terminals is provided so as to obtain an excellent heat transfer from the electrical elements 20, which act as power transistors and the board. The contact pads 22 are through the deep diffusion 113 coupled to the terminals 52. The terminals 53 are coupled to the drains of the power transistors 20. Although not shown here, a further deep diffusion may be present to reduce the contact resistance between the highly doped layer 112 and the regions in the substrate to be used as source. The gates of the power transistors are generally coupled to the control IC 30, and separate terminals are available for the input and output to the control IC 30. It is considered advantageous to position to contact pads 52 (and all those separately to the control IC) around the contact pads 53. That is advantageous for a simple layout of the board on which the assembly 100 is to be mounted. If desired, the oxide layer 12 may be patterned so as to enlarge the mutual movability of the islands 15. An additional passivation layer could be applied thereafter. The mesas 15 may be used as a mask for the patterning of oxide layer 12. It is however observed that the oxide layer 12 is suitably a thermal oxide with a thickness of about 500 nm and constitutes in itself an excellent passivation.

In this embodiment, testing of the assembly and of the elements in the carrier substrate can be carried out only after the patterning of the carrier substrate 10, and thus only after the assembly of active devices 30. Suitably, this testing is carried out before solder is provided on the solder balls. In order to limit yield loss, the elements in the carrier substrate 10 are preferably made on a relatively large scale and in well-known process technology and/or relatively vulnerable interconnects may be provided in twofold. Moreover, specific test pads may be provided as part of the interconnects 122 (or connected thereto) so as to enable testing of the solder connections 32 to the active devices 30 before the etching step.

FIGS. 10-15 shows in cross-sectional, diagrammatical view, which is not drawn to scale, different stages in a third embodiment of the invention. This embodiment aims at the integration of a BICMOS or CMOS circuit with a semiconductor device in a III-V substrate. The semiconductor device in the III-V substrate is for instance a power amplifier, a low-noise amplifier or even an opto-electronic device, such as a light-emitting diode. The example shown in the drawings comprises a carrier 10 with a BICMOS circuit and additionally including striplines, and an InP bipolar transistor as the semiconductor device 30.

Mechanically, the assembly 100 of this third embodiment combines two of the concepts of the first and second embodiment, and introduces a further one. As in the first embodiment, contact pads for connection to an external board are provided in the interconnect structure 21 of the carrier. In other words, the substrate 11 is completely removed at the area of the contact pad 22. As in the second embodiment, use is made of a flexible layer on top of the carrier 10. This flexible layer allows mechanical decoupling of the thinned and partially removed substrate 11 and the semiconductor device 30. An additional feature of this embodiment is the provision of a metal encapsulation, that acts at the same time as an effective heat spreader.

FIG. 10 shows the carrier 10 before assembly. It is provided with a substrate 11 having a first side 101 and an opposite second side 102. An oxide layer 12 is present on the first side 101. Electrical elements 20 are defined in the substrate 11 at this same, first side 101. The electric elements 20 form in this example an integrated circuit. It is specifically designed as a transceiver integrated circuit. For that reason, it is preferably that the circuit comprises both bipolar and CMOS transistors. An interconnect structure 21 is defined on top of the elements 20. It comprises extensions 22,23 to the first side 101 of the substrate 11. This structure 21 may be integrated with the conventional interconnect structure needed for the integrated circuit 20, although that is not necessary. The interconnect structure 21 comprises at least a first layer 211 and a second layer 212. The first layer 211 is used as interconnect for the terminals 52,53, that are to be formed from the extensions 22,23 at the first side 101 of the substrate 11. The second layer 212 is used as interconnect for the top side contact pads 25,26. These layers 211,212 are mutually separated with one or more insulating layers 213. Preferably, this insulating layer 213 comprises a material with a low dielectric constant, such as SilK™ as obtainable from Dow Corning. Additionally, a stack of materials may be used as the insulating layer 213. Vias 214 extend through the insulating layer 213 and are present between the first and the second layer 211, 212, or between contact pads 22,23,25,26. Additionally, in this design, a stripline 215 is defined in both layers 211, 212. This is enabled in that the first layer 211 of the interconnect structure, as far as coupled to the extension 22, is acting as a ground plane. In case that the interconnect structure 21 is fully integrated with the interconnect structure of the integrated circuit 20, the first layer 211 is preferably the bottom layer of the interconnect structure. However, the stripline is not the only possible construction. A capacitor could be created in the same manner, and also a multilayer inductor or an inductor with a shield may be obtained. Particularly for the capacitor, it would be suitable that the first and the second layer 211, 212 are disposed nearer to each other.

A passivation layer 24 is deposited on top of the structure 21, in a patterned manner so that only the contact pads 26 are covered. As will be explained later, the contact pads 26 are connected to a heat sink, while the contact pads 25 are connected to a further semiconductor device 30. Therefore, an additional metallization 125 is suitably deposited on the contact pads 25 only. The passivation layer 24 comprises a nitride by preference. A further insulating patterned layer 216 is present on the structure. This layer 216, for which for instance a photosensitive benzocyclobutane (BCB) or a photosensitive polyimide or acrylate may be used, acts as a spacer and defines the areas that act as contact pads 25,26.

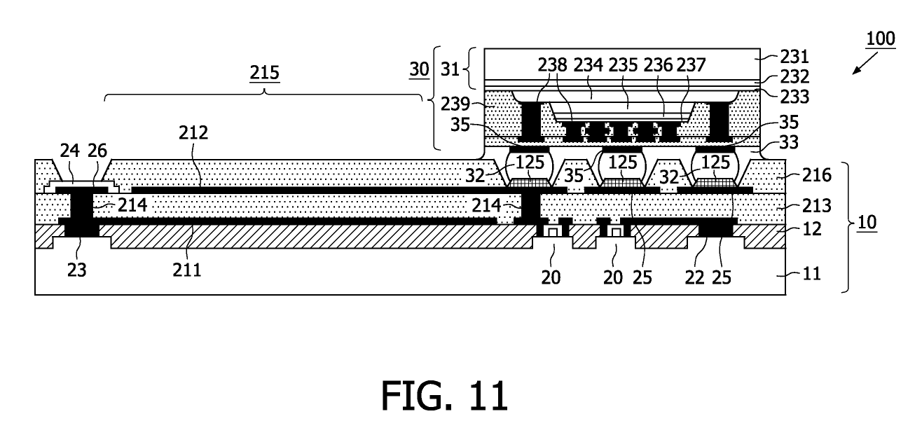

FIG. 11 shows the assembly 100 at a second stage in the processing. The active device 30 and the carrier 10 have been assembled here with a flip-chip technique and electrical contact is made with solder balls 32 between the contact pads 25 of the integrated circuit 20 defined in the carrier 10 and the contact pads 35 defined in the active device. An underfill 33 is provided for the protection of the solder balls 32 as well as for improvement of the mechanical reliability. The active device 30 is in this example an amplifier on a substrate 31 of a III-V semiconductor material, particularly InP. Alternatively, it could be a low-noise amplifier, an optoelectronic element, such as an optocoupler, a photodiode or a light-emitting diode, another integrated circuit, a MEMS-component or an acoustic filter. The substrate 31 comprises a substrate layer 231, an etch stop layer 232, in this example of InGaAs, a spacer layer 233, in this case an InP I spacer. On top of this substrate 31 with layer structure 231-233 a couple of patterned layers are defined, i.e. a InGaAs n⁺⁺ buried collector contact 234, an InP n collector 235, an InGaAs p base 236 and an InP n⁺⁺ emitter 237. Not shown but effectively present are an InP n⁻ spacer between the base 236 and the collector 237, as well as a InGaAs n⁺⁺ emitter contact. Metallizations 238, for instance of Au with a suitable barrier layer, such as TiN, provide the electrical coupling between the contacts of collector and emitter and the contact pads 35. The metallizations 39 and the layers 234-237 are embedded in dielectric material 239

FIG. 12 shows the assembly at a third stage in the processing. Herein, the substrate of the active device 30 is removed by etching. First the InP substrate 231 is removed. The etching in HCl stops on the InGaAs etch stop layer 232. Then the etch stop layer 232 is removed selectively towards the spacer 233. This results therein that the spacer layer 233 is exposed. Additionally, the passivation layer 24 on the top side contact pad 26 is opened so as to expose this contact pad 26. Although not shown here, an additional protection layer such as silicon nitride or silicon oxide may have been provided on the further insulating layer 216 and the underfill 33. Such protection layer protects the underlying layers against the etchants used to remove the substrate of the active device 30.

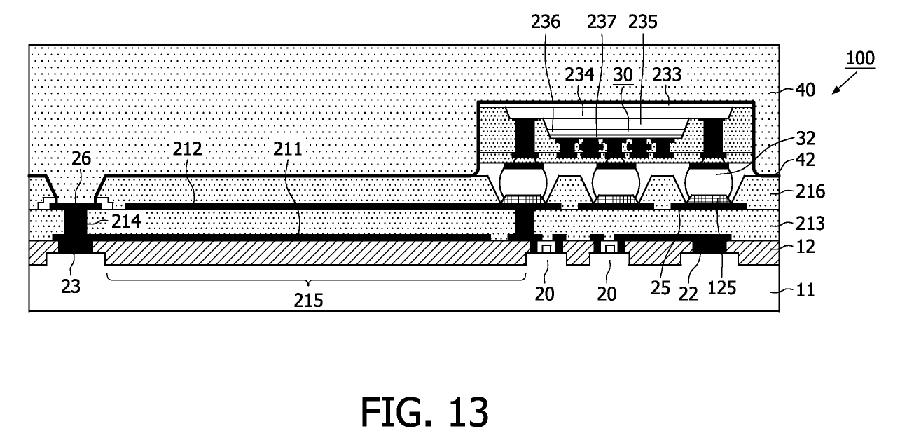

FIG. 13 shows the assembly 100 at a fourth stage in the processing. An encapsulation 40 has been applied to the assembly. In this case, use is made of a metal encapsulation 40. Although such metal encapsulation is most suitably made of copper, use can be made of other materials as well, for instance Al, Ni, Au or an alloy. Additionally, the metal encapsulation 40 may comprise more than one layer, e.g. an adhesion layer of Au could be applied on top of the copper metallization 40. If one desires a transparent layer, use could be made of ITO. The metallization is suitable applied by electroplating. Thereto, first a plating base 42 is provided on the further insulation layer 216 and on the exposed surface of the semiconductor device 30, for instance by sputtering. As the substrate 231, 232 of the semiconductor device 30 has been removed, its thickness excluding the solder balls 32 is in the order of 1-5 microns, preferably about 1 micron. The solder balls may be chosen at any size. Suitably, they extend only 5 to 15 microns above the further insulating layer 216. The resulting height difference between the further insulating layer 216 and the exposed spacer layer 233 is thus preferably in the order of 5-20 microns, and suitably about 10 microns. Such a distance does not lead to problems in the plating process, particularly as the foreseen thickness is in the order of 50-100 microns.

The result of this encapsulation has a couple of advantages. First, the stripline 215 is here a full stripline, as the signal carrying line (i.e. the second layer 212) is provided with a ground plane on both sides (i.e. the first layer 211 and the encapsulation 40).

A second advantage is the heat spreading. There is a short path from the semiconductor device 30 to the heat sink, such that heat can be dissipated easily. Moreover, the extension of the heat sink over the complete surface allows to create a uniform temperature in the device. Therewith the operation of the device can be optimized.

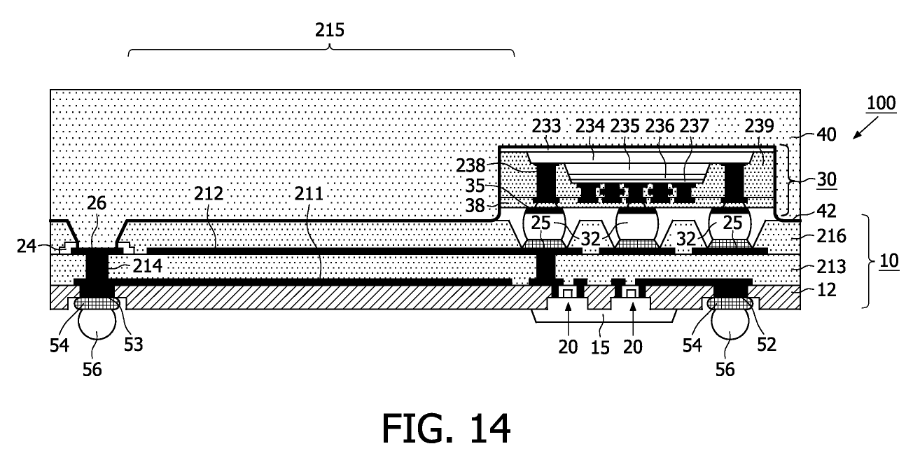

FIG. 14 shows the final assembly 100. After the provision of the encapsulation 40, the substrate 11 of the carrier is thinned by grinding and etching down to 20-50 μm. The copper encapsulation 40 renders the construction herein mechanically stable. Thereafter, the substrate 11 is etched selectively to form the terminals 52, 53 by exposing the extensions 22,23 to the interconnect structure 21, and to create the mesas 15 with the integrated circuit 20. The oxide layer 12 may be patterned.

Finally, the bottom side contact pads 22,23 are provided with a suitable metallization 241 and with solder balls 242 for placement onto an external board. The encapsulation 40 may be provided on a heat sink, or be connected to any other heat dissipating mechanism, such as a heat pipe. Alternatively, the encapsulation 40 may be used for carrying the assembly 100. The bottom side contact pads 22,23 may then be provided with bond wires or with a foil, such as a flexfoil.

### LIST OF REFERENCE NUMERALS

10 carrier
11 semiconductor substrate of the carrier
12 oxide layer on the semiconductor substrate 11
15 mesa-structure defined in the substrate 11
20 electrical elements
21 interconnect (structure)
22,23 extension of the interconnect structure
24 passivation layer
25,26 top side contact pads
30 active device
31 substrate of the active device 30
32 solder balls between carrier and active device
33 underfill
34 passivation layer of active device 30
35,36 contact pads of active device 30
40 encapsulation
41 adhesive
42 plating base for encapsulation
43 glass substrate
52,53 terminals
54 metallization on terminals
55 flux
56 solder balls
100 assembly
101 first side of the substrate 11
102 second side of the substrate 11
111 first layer of semiconductor substrate (highly doped n⁺⁺)
112 intrinsic layer in substrate 11
113 deep diffusion in substrate 11
120 dielectric layer
121 vertical interconnect areas
122 Interconnects
125 under bump metallization
211 first metal layer of interconnect structure 21
212 second metal layer of interconnect structure 21
213 insulating layer of interconnect structure 21
214 via through insulating layer 213
215 stripline defined in first & second metal layer 211,212
216 further insulating layer
231 substrate layer of substrate 31 of active device 30
232 etch-stop layer of substrate 31
233 spacer layer of substrate 31
234 buried collector contact
235 collector
236 base
237 emitter
238 metallization
239 dielectric material
241 metallization for the bottom side contact pads 22, 23
242 solder balls attached to the bottom side contact pads 22,23
300 printed circuit board
301 contact pads on printed circuit board

1. A method of manufacturing a semiconductor assembly, comprising the steps of:
providing a carrier comprising a semiconductor substrate with a first side and an opposite second side, and with at least one electrical element defined in the substrate at the first side, further comprising an interconnect structure that is present on the first side of the substrate, in which are defined a plurality of contact pads and at least one extension to the first side of the substrate, as well as interconnects from and to the at least one electrical element;
attaching and electrically coupling an active device to the contact pads in interconnect structure, said active device having a smaller surface area than the carrier;
encapsulating the electric device,
forming at least one island of semiconductor material by selectively removing the semiconductor substrate from its second side, and
defining terminals for external connections coupled to said extensions in the interconnect structure.

2. A method as claimed in claim 1, wherein the substrate is removed in such a way to form mesa-shaped islands.

3. A method as claimed in claim 1, wherein the carrier is provided with an oxide layer at the first side of the semiconductor layer, which oxide layer is locally removed around the mesa-shaped island.

4. A method as claimed in claim 1, wherein the interconnect structure comprises a stress relieving dielectric layer allowing relative movement between the active device and the mesa-shaped island.

5. A method as claimed in claim 1, wherein the mesa-shaped island and the terminals are formed simultaneously in the selective removal of the semiconductor substrate, in that the substrate is completely removed at the area of the extension so as to form the terminals.

6. A method as claimed in claim 1, wherein the terminals are formed on a surface of the mesa-shaped island and are electrically coupled to the extensions through the mesa-shaped island.

7. A method as claimed in claim 1, wherein the selective removal of the substrate exposes the extensions in the interconnect structure, after which a resin layer is provided on this second side, on which the terminals are defined that are coupled to said extensions by interconnects extending through the resin layer.

8. A method as claimed in claim 1, wherein the active device is provided with contact pads that are coupled to the contact pads of the carrier with solder balls.

9. A method as claimed in claim 8, wherein the substrate is thinned from its second side by grinding prior to its selective removal and wherein the solder balls are applied to the contact pads of the active device and are given a heat treatment so as to form a solder joint with the contact pads or any material thereon only after said thinning step.

10. A semiconductor assembly comprising:
a laterally limited semiconductor substrate region in which an electrical element is defined;
an interconnect structure overlying the substrate region and having an first side and a second side, which structure is at its first side provided with contact pads for coupling to an electric device, and is at its second side provided with connections to the electrical element,
terminals that are present at the second side of the interconnect structure, and coupled to the interconnect structure through extensions that are laterally displaced and isolated from the semiconductor substrate region,
an electric device coupled to the first side of the interconnect structure, and
an encapsulation extending on the first side of the interconnect structure so as to support it and encapsulating the electric device.

11. A semiconductor assembly as claimed in claim 10, wherein the encapsulation comprises a metal layer and the extension of the interconnect structure extends to the first side and is coupled to the metal layer.

12. A semiconductor assembly as claimed in claim 11, wherein the encapsulation comprises an insulating layer.

13. A semiconductor assembly as claimed in claim 11, wherein the active device comprises a controlling device for the electrical elements in the substrate regions.

14. A carrier substrate comprising a semiconductor substrate with a first side and an opposite second side, and with at least one electrical element defined in a region in the substrate at the first side, further comprising an interconnect structure that is present on the first side of the substrate, in which interconnect structure are defined:
a plurality of contact pads exposed at the second side, said contact pads corresponding to contact pads of an electric device to be assembled thereto;
at least one extension to the first side of the substrate that is present adjacent to the said substrate region,
interconnects between the at least one electrical element, extensions and contact pads according to a predefined design.
